(19) United States
(12) Patent Application Publication
(10) Pub. No.: US 2025/0125123 A1
(43) Pub. Date: Apr. 17, 2025

(54) SMART FACEPLATE USING SHAPE MEMORY ALLOY POPPET ACTUATORS

(71) Applicant: Applied Materials, Inc., Santa Clara, CA (US)

(72) Inventors: Nitish Kumar SINGH, Bangalore (IN); Barath KUMAR, Bangalore (IN); Sumesh SURESH, Bangalore (IN)

(21) Appl. No.: 18/896,247

(22) Filed: Sep. 25, 2024

(30) Foreign Application Priority Data
Oct. 11, 2023 (IN) 202341068179

(51) Int. Cl. H01J 37/32; F03G 7/06

(52) U.S. Cl. CPC H01J 37/3244; F03G 7/0614

(57) ABSTRACT

Embodiments of the present disclosure relate to a faceplate that implements poppets to vary nozzle cross-sections. In one embodiment, a faceplate is provided. The faceplate includes a body, a plurality of holes in the body, and a plurality of poppet assemblies. The poppet assemblies include a poppet configured to travel in a first portion of the hole and create a variable passage in a second portion of the hole. The poppet assemblies further include a first spring connected to the poppet and operable to move the poppet in a first direction when connected to an electrical power, and a second spring connected to the poppet and operable to move the poppet in a second direction that is opposite the first direction when the electrical power is reduced or terminated.

### BACKGROUND

### Field

Embodiments of the present disclosure generally relate to a method and apparatus for distributing a gas in a processing chamber. Specifically, embodiments of the present disclosure relate to a faceplate that implements poppets to vary nozzle cross-sections.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further processing. Often, these processes are used in a repetitive fashion to fabricate various layers of an electronic device, such as a semiconductor device.

Conventional processing chambers utilize showerheads to alter the flow of the gases to the substrate in order to achieve desired layer geometries thereon. However, current showerheads have fixed nozzle diameters. In order to change the nozzle diameter, the faceplate needs to be changed out. Having multiple designs of faceplates often leads to downtime to replace one faceplate with another faceplate of a different design for a new process operation. Such designs increase the cost of device manufacturing and lower the throughput of the processing systems.

Therefore, there is a need for improved faceplates for processing substrates.

### SUMMARY

In one embodiment, a faceplate is provided. The faceplate includes a body, a plurality of holes in the body, and a plurality of poppet assemblies. Each hole included in the plurality of holes has at least a first portion with a first diameter and a second portion with a second diameter. The poppet assemblies include a poppet configured to travel in the first portion of the hole and create a variable passage in the second portion of the hole. The poppet assemblies further include a first spring connected to the poppet and operable to move the poppet in a first direction when connected to an electrical power, and a second spring connected to the poppet and operable to move the poppet in a second direction that is opposite the first direction when the electrical power is reduced or terminated.

In another embodiment, a processing chamber is provided. The processing chamber includes an inlet port disposed in a lid, and a faceplate disposed below the lid beneath the inlet port. The faceplate includes a body, and a plurality of holes extending through the body of the faceplate. Gas from the inlet port flows through the holes. The faceplate further includes a plurality of poppet assemblies disposed in the holes; the poppet assemblies are operable to vary a flow area of the holes through actuating the poppet assemblies, and a plurality of wires operable to supply an electrical power to the poppet assemblies to effect a position of the poppet assemblies. The processing chamber further includes a power supply to supply the electrical power to the wires, and a controller operable to control the actuating of the poppet assemblies.

In another embodiment, a method for adjusting a flow through a faceplate is provided. The method includes supplying, via a power supply, electrical power to a plurality of poppet assemblies to cause each poppet assembly to move from a first position to a second position. The plurality of poppet assemblies are disposed in a plurality of holes of a faceplate, and the electrical power is being applied to a first spring included in each poppet assembly. The method further includes flowing a gas through the plurality of holes in the faceplate, and reducing or terminating the electrical power supplied to the plurality of poppet assemblies to cause a second spring included in each poppet assembly to return the poppet assembly to the first position.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a cross-sectional view of a processing chamber, according to one embodiment.

FIG. 2 is an isometric view of a poppet assembly, according to one embodiment.

FIG. 3 is a top view of a faceplate, according to one embodiment.

FIG. 4 is a flow diagram of a method of operating a faceplate with a poppet assembly, according to one embodiment.

FIG. 5A-5B are cross-sectional views of the faceplate during the method of FIG. 4, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a method and apparatus for distributing a gas in a processing chamber. Specifically, embodiments of the present disclosure relate to a faceplate that implements poppets to vary nozzle cross-sections. A plurality of poppet assemblies are coupled to the faceplate and are operable to vary the nozzle cross-sections of holes in the faceplate in order to modify a flow profile of a gas flowing therethrough. A method of processing a substrate using the gas distribution is also disclosed.

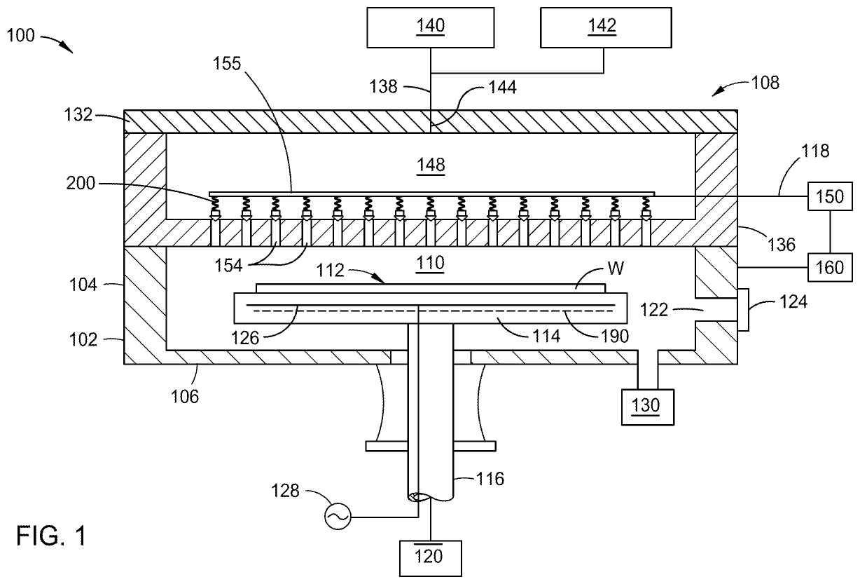

FIG. 1 is a schematic arrangement of an exemplary processing chamber 100 according to one embodiment. The processing chamber 100 has a body 102 having a sidewall 104 and base 106. A lid assembly 108 couples to the body 102 to define a processing volume 110 therein. The body 102 is generally formed from a metal, such as aluminum or stainless steel, but any material suitable for use with processing therein may be utilized. A substrate support 112 is disposed within the processing volume 110 and supports a substrate W during processing within the processing chamber 100. The substrate support 112 includes a support body 114 coupled to a shaft 116. The shaft 116 is coupled to a lower surface of the support body 114 and extends out of the body 102 through an opening in the base 106. The shaft 116 is coupled to an actuator 120 to vertically move the shaft 116, and the support body 114 coupled thereto, between a substrate loading position and a processing position. A vacuum system 130 is fluidly coupled to the processing volume 110 in order to evacuate gases from the processing volume 110.

To facilitate processing of a substrate W in the processing chamber 100, the substrate W is disposed on the upper surface of the support body 114, opposite of the shaft 116. A port 122 is formed in the sidewall 104 to facilitate ingress and egress of the substrate W into the processing volume 110. A door 124, such as a slit valve, is actuated to selectively allow the substrate W to pass through the port 122 to be loaded onto, or removed from, the substrate support 112. An electrode 126 is optionally disposed within the support body 114 and electrically coupled to a power source 128 through the shaft 116. The electrode 126 is selectively biased by the power source 128 to create an electromagnetic field to chuck the substrate W to the upper surface of the support body 114 and/or to facilitate plasma generation or control. In certain embodiments, a heater 190, such as a resistive heater, is disposed within the support body 114 to heat the substrate W disposed thereon.

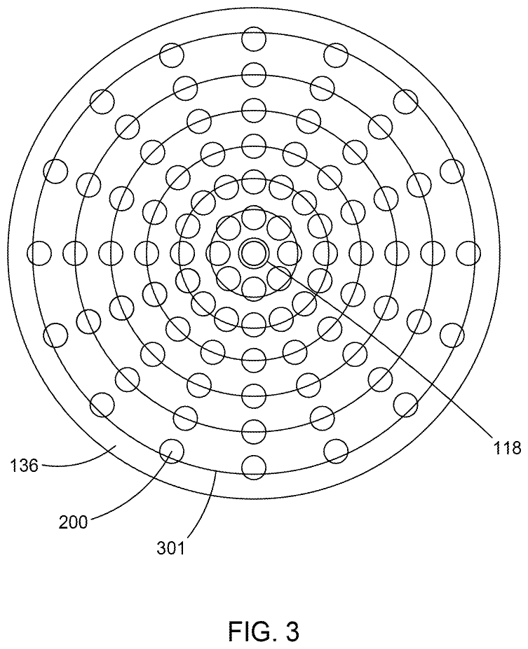

The lid assembly 108 includes a lid 132, and a faceplate 136. The faceplate 136 is coupled to the lid 132 and together with the lid 132 defines a gas volume 148. The faceplate 136 is connected to the sidewall 104. The faceplate 136 is coupled to the base 106 and together with the base 106 defines the processing volume 110. The faceplate 136 includes a circular shaped disk with a disk diameter. The disk diameter is between 500 mm and 600 mm. The faceplate 136 includes a plurality of holes 154 disposed throughout the faceplate 136. The faceplate is further described in conjunction with FIG. 3.

An inlet port 144 is disposed within the lid 132. The inlet port 144 is coupled to a gas conduit 138. The gas conduit 138 allows a gas to flow from a first gas source 140, such as a process gas source, through the inlet port 144 into the gas volume 148. A second gas source 142, such as a cleaning gas source, is optionally coupled to the gas conduit 138. The first gas source 140 supplies a process gas, such as an etching gas or a deposition gas, to the processing volume 110 to etch or deposit a layer on the substrate W. The second gas source 142 supplies a cleaning gas to the processing volume 110 in order to remove particle depositions from internal surfaces of the processing chamber 100.

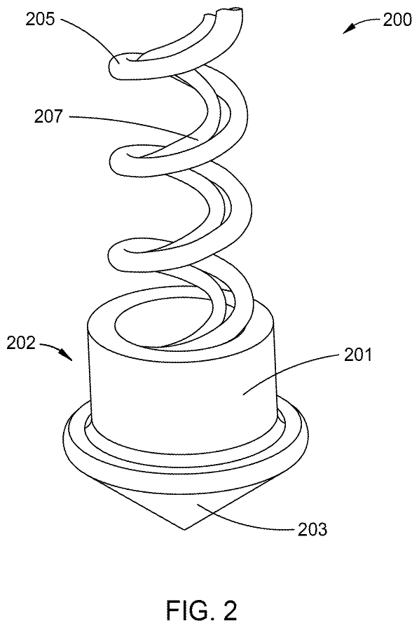

The holes 154 are disposed through the faceplate 136. The holes 154 allow fluid communication between the processing volume 110 and the gas volume 148. During operation, a gas is permitted to flow from the inlet port 144 into the gas volume 148. Then, the gas flows through the holes 154 in the faceplate 136 into the processing volume 110. One or more holes 154 of the plurality of holes 154 are partially covered by poppet assemblies 200. The poppet assemblies 200 are disposed partially in the holes 154. Each of the poppet assemblies 200 are supported by a housing 155. Accordingly, the housing 155 keeps the poppet assemblies 200 steady while actuating throughout the holes 154. The housing 155 is a part of the faceplate 136. The housing 155 is designed to not impede the flow of gas through the faceplate 136. Further, the plurality of holes 154 have a total diameter between 10 mils to 120 mils. The poppet assemblies 200 are connected to a power supply 150 and a controller 160. The power supply 150 connects to the poppet assemblies 200 via a power supply wire 118. The poppet assemblies 200 are further described in FIG. 2.

The power supply 150 may be of any suitable type, such as a linear power supply, switching power supply, uninterruptable power supply, alternating current (AC) power supply, direct current (DC) power supply, programmable power supply, high voltage power supply, or radio frequency (RF) power supply, according to the needs of the processing chamber 100 or the poppet assemblies 200.

The power supply 150 includes at least a power input and a power output. The power supply 150 may include a transformer, DC-to-DC converter, rectifier, voltage regulator, and/or filter. The power supply 150 power input may be configured accept an alternating current (AC) input or direct current (DC) input. The power supply 150 power output may be configured to provide an AC or DC source. The power supply 150 may include a transformer to accept an AC input and which may then be stepped up or down to match the voltage level required. The power supply 150 may include a DC-to-DC converter such as a buck converter, boost converter, or buck-boost converter to step up or step down a DC input to match the voltage required. The power supply 150 may include a rectifier, of suitable topology, to accept an AC input and convert the AC input to a DC output. The power supply 150 may include a voltage regulator employed to maintain a constant output voltage despite fluctuations in the input voltage or variations in the load. The voltage regulator may be of any suitable topology, for example a liner regulator or switching regulator. In some embodiments, the power supply 150 may include a filter configured to smooth out or reduce unwanted variations, harmonics, or noise in the output voltage or current. In some embodiments, the filter may include a capacitive filter, inductive filter, or inductive-capacitive filter of suitable topology. In some embodiments, the filter may be an active filter, passive filter, digital filter, or a combination thereof. In some embodiments, the power supply 150 may include various protection mechanisms such as overcurrent protection, overvoltage protection, power conditioning, and/or short circuit protection to safeguard both the power supply, the processing chamber 100, the poppet assemblies 200, and the controller 160.

The controller 160 can control processes in the processing chamber 100. The controller 160 can control the flow of gases from the gas sources 140 and 142. The controller may control the power supply 150 supplying electrical power to the processing chamber 100 and the poppet assemblies 200. The controller 160 is in communication with the processing chamber 100 and is used to control processes and methods, such as the operations of the methods described herein.

The controller 160 is configured to receive data and to input instructions to the components of the processing chamber 100. The controller 160 is equipped with or in communication with a system model of the processing chamber 100. The system model includes a heating model, a film uniformity model, a film deposition rate model, a coating model, a rotational position model, and/or a gas flow model. The system model is a program configured to estimate parameters (such as gas flow rate, a gas pressure, a processing temperature of the substrate support 112 and/or the substrate W, a rotational position of component(s), a heating profile, a coating condition, and/or an etching condition) within the processing chamber 100 throughout a deposition operation and/or an etching operation. The controller 160 is further configured to store readings and calculations. The readings and calculations include previous sensor readings, such as any previous sensor readings within the processing chamber 100. The readings and calculations further include the stored calculated values from after the sensor readings are measured by the controller 160 and run through the system model. Therefore, the controller 160 is configured to both retrieve stored readings and calculations as well as save readings and calculations for future use. Maintaining previous readings and calculations enables the controller 160 to adjust the system model over time to reflect a more accurate version of the processing chamber 100.

The controller 160 can monitor, estimate an optimized parameter, calibrate one or more flow rate sensors, generate an alert on a display, halt a deposition operation, initiate a chamber downtime period, delay a subsequent iteration of the deposition operation, initiate an etching operation, halt the etching operation, adjust a heating power, and/or otherwise adjust the process recipe.

The controller 160 includes a central processing unit (CPU) (e.g., a processor), a memory containing instructions, and support circuits for the CPU. The controller 160 controls various items directly, or via other computers and/or controllers. In one or more embodiments, the controller 160 is communicatively coupled to dedicated controllers, and the controller 160 functions as a central controller.

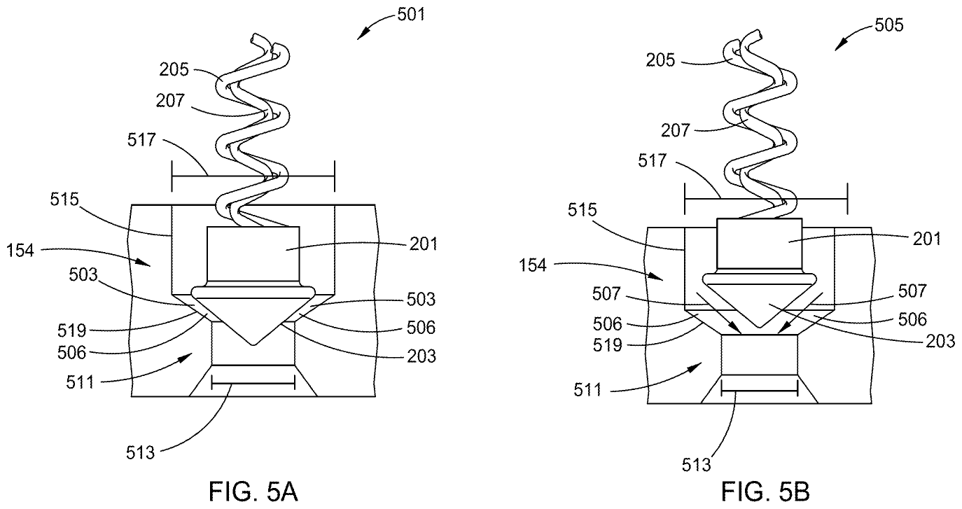

The controller 160 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 160 are coupled to the CPU for supporting the CPU. The support circuits include cache, power supplies, clock circuits, input/output circuitry and subsystems, and the like. Operational parameters (e.g., add) and operations are stored in the memory as a software routine that is executed or invoked to turn the controller 160 into a specific purpose controller to control the operations of the various chambers/modules described herein. The controller 160 is configured to conduct any of the operations described herein. The instructions stored on the memory, when executed, cause one or more of operations of: FIG. 1, FIG. 2, FIG. 3, FIG. 5A-5B, and/or method 400 to be conducted in relation to the processing chamber 100. The controller 160 and the processing chamber 100 are at least part of a system for processing substrates.

The various operations described herein (such as the operations of FIG. 1, FIG. 2, FIG. 3, FIG. 5A-5B, and/or method 400) can be conducted automatically using the controller 160, or can be conducted automatically or manually with certain operations conducted by a user.

In one or more embodiments, the controller 160 includes a mass storage device, an input control unit, and a display unit. The controller 160 monitors, process gas flow, and/or the purge gas flow, the amount of electrical power provided by the power supply 150, and the position of the poppet assemblies 200. In one or more embodiments, the controller 160 includes multiple controllers, such that the stored readings and calculations and the system model are stored within a separate controller from the controller 160 which controls the operations of the processing chamber 100. In one or more embodiments, all of the system model and the stored readings and calculations are saved within the controller 160.

FIG. 2 is an isometric view of a single poppet assembly 200. The poppet assembly 200 includes base 201, a stopper 203, a first spring 205, and a second spring 207. The base 201 is connected to the stopper 203. The base 201 and the stopper 203 are fused together to form a single part, a poppet 202. The base 201 and the stopper 203 may include polytetrafluoroethylene (PTFE) or a similar material. The base 201 is configured to travel above the faceplate 136 and in the holes 154. The stopper 203 is configured to create a variable passage for gases to travel through the holes 154. The stopper 203 moves throughout the hole 154 with the base 201. The first spring 205 and the second spring 207 are connected to the base 201. The first spring 205 and the second spring 207 are configured to move the base 201 and stopper 203.

The first spring 205 is fabricated from a shape memory alloy. The shape memory alloy is formed into a first wire that is wound into a spring. In some embodiments, the shape memory alloy is nitinol (Nickel Titanium). In some embodiments, the shape memory includes Iron Manganese Silicon, Copper Zinc Aluminum, Copper Aluminum Nickel, or some combination thereof. The shape memory alloy changes shape in the presence of an electrical power. The electrical power increases the temperature of the first spring 205, causing the shape memory alloy to contract and moves the poppet assembly 200 in a first direction away from the hole 154. The first spring 205 has a first coil diameter between 3 mm to 6 mm. The wire forming the first spring 205 has a first wire diameter between 0.1 mm to 0.3 mm. The first spring 205 is connected to the housing 155.

The second spring 207 is a traditional spring. The second spring 207 is formed from a second wire. The second wire may include stainless steel (SST) or a similar material. The second spring 207 has a second coil diameter that is less than the first coil diameter of the first spring 205. The second spring 207 is operable to assist moving the poppet assembly 200 in a second direction towards the hole 154. The second direction is an opposite direction of the first direction. In some embodiments, the first spring 205 and the second spring 207 are enclosed in a housing (not shown) to protect the springs from the gases. The second spring 207 is connected to the housing 155. In some embodiments, the housing 155 extends around the first spring 205 and the second spring 207 to protect the springs from gases flowing through the holes 154.

FIG. 3 is a top view of the faceplate 136. The poppet assemblies 200 are positioned above the holes 154 of the faceplate 136. Activation wires 301 connect to each first spring 205 of the poppet assemblies 200. The activation wires 301 all connect to the power supply wire 118 connected to the power supply 150. The power supply 150 sends the electrical power down the power supply wire 118 that passes through to the activation wires 301. The electrical power passes through the activation wires 301 and is applied to the first springs 205. The electrical power contacting the first springs 205 actuates the first springs 205. The activation wires 301 connect to the first springs 205 in a metal fixture disposed in the housing 155.

FIG. 3 shows a circular pattern of holes 154 arranged in concentric circles. In other embodiments, different patterns of holes 154 are contemplated. For example, other hole patterns include a hexagonal pattern where each hole is surrounded by six others at fixed angles, a rectangular grid where each hole is in a square grid, triangular grid where the holes form equilateral triangles, a staggered circular, a staggered rectangular, a staggered triangular, a spiral pattern, a radial pattern, an asymmetric pattern, a honey comb pattern, or a spirograph pattern are also contemplated.

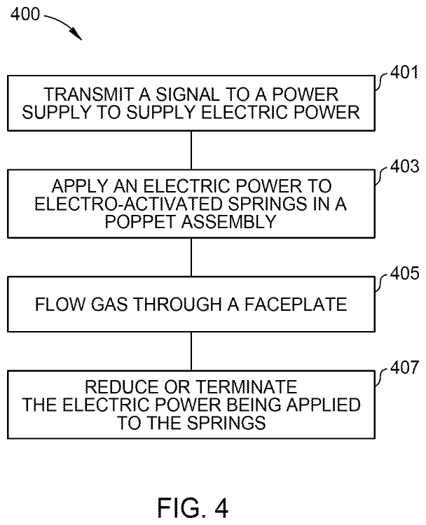

FIG. 4 is a flow diagram of a method 400 of operating the faceplate 136 with the poppet assemblies 200. FIG. 5A-5B are cross-sectional views of the faceplate 136 during the method 400 of FIG. 4.

At operation 401, a signal is transmitted to the power supply 150 to supply an electric power. The controller 160 signals the power supply 150 to supply electrical power to the poppet assemblies 200. The controller 160 indicates the amount of electrical power, which determines the distance actuated by the first spring 205. The distance actuated by the first spring 205 determines a distance between each poppet assembly 200 and a corresponding hole 154 and, as a result, a size of a cross-section of a gas channel 506. The gas channel 506 is a passage to allow gas to flow through each hole 154. The gas channel 506 is defined between the stopper 203 of the poppet assembly 200 and first section 511 of the hole 154.

The poppet assemblies 200 start in a first position 501, as shown in FIG. 5A. The first spring 205 and the second spring 207 are in a starting position. The hole 154 has a first section 511 and a second section 515. The first section 511 has a first diameter 513. In some embodiments, the first diameter 513 is equal to the total diameter of the holes 154 between 10 mils to 120 mils. The second section 515 has a second diameter 517. The second diameter 517 is between 250 mils and 300 mils. The first section 511 is shaped to mirror the shape of the stopper 203. The first section 511 has a stepped surface 519 that starts with the second diameter 517 and moves to the first diameter 513. In some embodiments, the stepped surface 519 contacts the stopper 203 in the first position 501, and the gas channel 506 is closed allowing no gas to pass through. In some embodiments as shown in FIG. 5A, the stepped surface 519 does not contact the stopper 203, and a first cross-section 503 of the gas channel 506 is a narrow opening allowing gas to pass through a first flow area. The first cross-section 503 is directly related to the first position 501.

At operation 403, electrical power is supplied to the poppet assemblies 200. The electrical power is supplied to the activation wires 301 by the power supply 150 via the power supply wire 118. The first springs 205 contact the activation wires 301, passing the electrical power to the first springs 205. Subsequently, the electrical power heats the first springs 205, causing the shape memory alloy to contract. The first springs 205 contracting causes the poppet assemblies 200 to actuate a distance away from the holes 154. The poppet assemblies 200 move the distance that corresponds to the electrical power provided by the power supply 150. In some embodiments, multiple power supply wires 118 are connected to multiple activation wires 301, allowing different magnitudes of electrical power to be supplied to different poppet assemblies 200. Accordingly, different poppet assemblies 200 can be actuated different distances away from the holes 154.

The poppet assemblies 200 move to a second position 505 as shown in FIG. 5B. The first spring 205 and the second spring 207 are in an actuated position. The contracting of the first spring 205 and the second spring 207 raises the base 201 and the stopper 203 of the poppet assembly 200. The stopper 203 moves a distance away from the stepped surface 519, creating a second cross-section 507 of the gas channel 506. The second cross-section 507 is an opening greater than the opening of the first cross-section 503 of the gas channel 506, allowing more gas to pass through. The gas channel 506 have the smaller first cross-section 503 caused by the poppet assemblies 200 being in the first position. The second cross-section 507 that the gas travels through is directly related to the electrical power supplied by the power supply 150. In some embodiments, the first cross-section 503 is a smaller cross-section than the second cross-section 507. In some embodiments, the electrical power is varied across the poppet assemblies 200, leading to some first springs 205 to receive different electrical power. The different electrical powers cause the cross-sections of gas channels 506 to be varied across the holes 154.

At operation 405, gas is flowed through the faceplate 136. Gas enters the gas volume 148 via the inlet port 144. Gas is supplied to the inlet port 144 from the first gas source 140 and the second gas source 142 via the gas conduit 138. In some embodiments, a first gas is supplied from the first gas source 140, and a second gas is supplied from the second gas source 142. Gases in the gas volume 148 flow to the processing volume 110 through the faceplate 136. The gases in the gas volume 148 pass through the second cross-section 507 of the gas channel 506 created by the poppet assemblies 200 in the holes 154. The gases flow towards the substrate support 112. The gases in the gas volume 148 may then be used to deposit, treat, or etch the substrate W positioned on the substrate support 112.

In some embodiments, multiple gases are used for operation 405. In some embodiments, after operation 405, operation 403 is repeated with a different electrical power to move the poppet assemblies 200 to a third position. The third position creates a different cross section of the gas channel 506 and operation 405 is repeated with the gas flowing through the different cross-section. This process can be repeated multiple times. In some embodiments, gas is flowed through the faceplate 136 prior to operation 401, during which the poppet assemblies 200 are in the first position 501. The gas is then flowed through the first cross-section 503 of the gas channels 506.

At operation 407, the power supply 150 reduces or terminates the electrical power being supplied to the first springs 205. As a result, the shape memory alloy in the first springs 205 causes the first springs 205 to expand or return to the starting position. In various embodiments, the second spring 207 provides a spring force to assist returning the first spring 205 to the start position. Once operation 407 is completed, the poppet assembly is in the first position 501 described in FIG. 5A.

In summation, embodiments of the present disclosure generally relate to a method and apparatus for distributing a gas in a processing chamber. Specifically, embodiments of the present disclosure relate to a faceplate that implements poppets to vary nozzle cross-sections. Poppet assemblies are coupled to the faceplate and are operable to vary the nozzle cross-sections of holes in the faceplate in order to modify a flow profile of a gas flowing therethrough. A method of processing a substrate using the gas distribution is also disclosed. Benefits of the disclosure include the ability to control the flow area of gases through the faceplate. Controlling the flow area of gases through the faceplate allows one faceplate to be used for a variety of different processes. Using one faceplate for multiple processes reduces the costs that would otherwise be incurred by implementing multiple faceplates. Additionally, time that would be needed to replace faceplates is eliminated. The flow area can be varied across the faceplate to ensure uniform deposition across the substrate. The embodiments of the present disclosure are retrofittable in current processing chambers, reducing cost.

While the foregoing is directed to embodiments of the present disclosure, other and further embodiments of the disclosure may be devised without departing from the basic scope thereof, and the scope thereof is determined by the claims that follow.

What is claimed is:

1. A faceplate, comprising:
a body;
a plurality of holes in the body, wherein each hole included in the plurality of holes has at least a first portion with a first diameter and a second portion with a second diameter; and
a plurality of poppet assemblies, comprising:
a poppet configured to travel in the second portion of the hole and create a variable passage in the first portion of the hole;
a first spring connected to the poppet and operable to move the poppet in a first direction when connected to an electrical power; and
a second spring connected to the poppet and operable to move the poppet in a second direction that is opposite the first direction when the electrical power is reduced or terminated.

2. The faceplate of claim 1, wherein the first spring comprises a shape memory alloy.

3. The faceplate of claim 2, wherein the shape memory alloy comprises nickel titanium, iron manganese silicon, copper zinc aluminum, copper aluminum nickel, or some combination thereof.

4. The faceplate of claim 1, wherein the first spring has a coil diameter between 3 mm to 6 mm and a wire diameter between 0.1 mm and 0.3 mm.

5. The faceplate of claim 1, wherein the first diameter of the first portion of the holes is between 10 mils and 120 mils and the second diameter of the second portion of the holes is between 250 mils and 300 mils.

6. The faceplate of claim 1, wherein the body has a disk diameter between 500 mm and 600 mm.

7. The faceplate of claim 1, wherein, for a first poppet assembly included in the plurality of poppet assemblies, when the first spring is connected to the electrical power, a gas channel defined between the poppet and the second portion of the hole has a cross-section that is greater than when the electrical power is reduced or terminated.

8. The faceplate of claim 7, wherein the first direction is away from the second portion of the hole and the second direction is towards the second portion of the hole.

9. A processing chamber, comprising:
an inlet port disposed in a lid;
a faceplate disposed below the lid beneath the inlet port, the faceplate comprising:
a body:
a plurality of holes extending through the body of the faceplate, wherein gas from the inlet port flows through the holes;
a plurality of poppet assemblies disposed in the holes, the poppet assemblies operable to vary a flow area of the holes through actuating the poppet assemblies;
a plurality of wires operable to supply an electrical power to the poppet assemblies to effect a position of the poppet assemblies;
a power supply to supply the electrical power to the wires; and
a controller operable to control the actuating of the poppet assemblies.

10. The processing chamber of claim 9, wherein each poppet assembly included in the plurality of poppet assemblies further comprises:
a poppet configured to travel in the hole and create a variable passage in the hole
a first spring connected to the body configured to move the body when connected to an electrical power; and
a second spring connected to the body configured to move the body in the opposite direction of the first spring when the electrical power is removed.

11. The faceplate of claim 10, wherein the first spring comprises a shape memory alloy.

12. The faceplate of claim 10, wherein the first spring has a coil diameter between 3 mm to 6 mm and a wire diameter between 0.1 mm and 0.3 mm.

13. The faceplate of claim 10, wherein a first diameter of a first portion of the holes is between 10 mils and 120 mils and a second diameter of a second portion of the holes is between 250 mils and 300 mils.

14. The faceplate of claim 9, wherein the body of the faceplate has a disk diameter between 500 mm and 600 mm.

15. A method for adjusting a flow through a faceplate, comprising:
supplying, via a power supply, electrical power to a plurality of poppet assemblies to cause each poppet assembly to move from a first position to a second position, the plurality of poppet assemblies disposed in a plurality of holes of a faceplate, and the electrical power being applied to a first spring included in each poppet assembly;
flowing a gas through the plurality of holes in the faceplate; and
reducing or terminating the electrical power supplied to the plurality of poppet assemblies to cause a second spring included in each poppet assembly to return the poppet assembly to the first position.

16. The method of claim 15, wherein, for a first poppet assembly included in the plurality of poppet assemblies, when the first spring is connected to the electrical power, a gas channel defined between the poppet and the hole has a cross-section that is greater than when the electrical power is reduced or terminated.

17. The method of claim 16, wherein the gas flowing through the plurality of holes in the faceplate flows through the gas channels towards a substrate support.

18. The method of claim 16, further comprising prior to supplying the electrical power, a gas is flowed through the gas channels towards a substrate support, wherein the gas channels have a smaller cross-section caused by the poppet assemblies being in the first position.

19. The method of claim 16, further comprising:
supplying a different electrical power to each of the first springs of the poppet assemblies, the poppet assemblies actuating to a third position via the first springs creating a different cross-section for the gas channels; and
flowing the gas through the plurality of holes in the faceplate.

20. The method of claim 15, wherein supplying the electrical power to the plurality of poppet assemblies comprises supplying a different magnitude of electrical power to different poppet assemblies included in the plurality of poppet assemblies to cause the second position to vary across the different poppet assemblies.
